(19) United States
(12) Patent Application Publication
(10) Pub. No.: US 2025/0275167 A1
(43) Pub. Date: Aug. 28, 2025

(54) SEMICONDUCTOR DEVICE AND METHOD FOR MANUFACTURING THE SAME

(71) Applicant: KABUSHIKI KAISHA TOSHIBA, Tokyo (JP)

(72) Inventors: Jumpei TAJIMA, Mitaka (JP); Toshiki HIKOSAKA, Kawasaki (JP)

(73) Assignee: KABUSHIKI KAISHA TOSHIBA, Tokyo (JP)

(21) Appl. No.: 19/018,330

(22) Filed: Jan. 13, 2025

(30) Foreign Application Priority Data
Feb. 22, 2024 (JP) 2024-025872

(51) Int. Cl. H10D 30/47; H01L 23/31; H10D 30/01; H10D 62/85; H10D 64/00

(52) U.S. Cl. CPC H10D 30/475; H01L 23/3171; H01L 23/3192; H10D 30/015; H10D 62/8503; H10D 64/112

(57) ABSTRACT

According to one embodiment, a semiconductor device includes a first electrode, a second electrode, a third electrode, and a semiconductor member. The second electrode includes a first electrode portion and a second electrode portion. The semiconductor member includes a first semiconductor layer, a second semiconductor layer, and a third semiconductor layer. The first semiconductor layer includes Alₓ₁Ga₁₋ₓ₁N (0≤x1<1). The first semiconductor layer includes first to sixth partial regions. The second semiconductor layer includes Alₓ₂Ga₁₋ₓ₂N (0<x2<1, x1<x2). The second semiconductor layer includes a first semiconductor portion, a second semiconductor portion, and a third semiconductor portion. The third semiconductor layer includes Al, Ga and N. The third semiconductor layer includes a first portion including Al_{y1}Ga_{1-y1}N (0<y1≤1), and a second portion including Al_{y2}Ga_{1-y2}N (0≤y2<1, y2<y1).

### CROSS-REFERENCE TO RELATED APPLICATIONS

This application is based upon and claims the benefit of priority from Japanese Patent Application No. 2024-025872, filed on Feb. 22, 2024; the entire contents of which are incorporated herein by reference.

### FIELD

Embodiments described herein relate generally to a semiconductor device and a method for manufacturing the same.

### BACKGROUND

For example, stable characteristics are desired in semiconductor devices.

### BRIEF DESCRIPTION OF THE DRAWINGS

FIG. 1 is a schematic cross-sectional view illustrating a semiconductor device according to a first embodiment;

FIG. 2 is a schematic plan view illustrating the semiconductor device according to the first embodiment;

FIG. 3 is a schematic diagram illustrating the semiconductor device according to the first embodiment;

FIG. 4 is a schematic diagram illustrating a semiconductor device according to the first embodiment;

FIG. 5 is a schematic diagram illustrating a semiconductor device according to the first embodiment;

FIG. 6 is a schematic diagram illustrating a semiconductor device according to the first embodiment;

FIG. 7 is a cross-sectional view corresponding to the A1-A2 line cross section in FIG. 2;

FIG. 8 is a cross-sectional view corresponding to the A1-A2 line cross section in FIG. 2;

FIGS. 9A to 9C are schematic diagrams illustrating a semiconductor device according to the first embodiment;

FIGS. 10A to 10C are schematic diagrams illustrating a semiconductor device according to the first embodiment;

FIG. 11 is a schematic cross-sectional view illustrating a semiconductor device according to the first embodiment;

FIG. 12 is a schematic cross-sectional view illustrating a semiconductor device according to the first embodiment;

FIG. 13 is a schematic cross-sectional view illustrating a semiconductor device according to the first embodiment;

FIG. 14 is a schematic cross-sectional view illustrating a semiconductor device according to the first embodiment;

FIGS. 15A to 15C are schematic cross-sectional views illustrating a method for manufacturing the semiconductor device according to a second embodiment; and

FIGS. 16A and 16B are schematic cross-sectional views illustrating a method for manufacturing the semiconductor device according to the second embodiment.

### DETAILED DESCRIPTION

According to one embodiment, a semiconductor device includes a first electrode, a second electrode, a third electrode, and a semiconductor member. A direction from the first electrode to the second electrode is along a first direction. The second electrode includes a first electrode portion and a second electrode portion. The second electrode portion is connected to the first electrode portion. A position of the third electrode in the first direction is between a position of the first electrode in the first direction and a position of the second electrode in the first direction. The semiconductor member includes a first semiconductor layer, a second semiconductor layer, and a third semiconductor layer. The first semiconductor layer includes Alₓ₁Ga₁₋ₓ₁N (0≤x1<1). The first semiconductor layer includes a first partial region, a second partial region, a third partial region, a fourth partial region, a fifth partial region, and a sixth partial region. A second direction from the first partial region to the first electrode crosses the first direction. A direction from the second partial region to the first electrode portion is along the second direction. A direction from the sixth partial region to the second electrode portion is along the second direction. A direction from the third partial region to the third electrode is along the second direction. A position of the fourth partial region in the first direction is between a position of the first partial region in the first direction and a position of the third partial region in the first direction. A position of the fifth partial region in the first direction is between the position of the third partial region in the first direction and a position of the second partial region in the first direction. A position of the sixth partial region in the first direction is between the position of the fifth partial region in the first direction and the position of the second partial region in the first direction. The second semiconductor layer includes Alₓ₂Ga₁₋ₓ₂N (0<x2<1, x1<x2). The second semiconductor layer includes a first semiconductor portion, a second semiconductor portion, and a third semiconductor portion. A direction from the fourth partial region to the first semiconductor portion is along the second direction. A direction from the fifth partial region to the second semiconductor portion is along the second direction. A direction from the sixth partial region to the third semiconductor portion is along the second direction. The third semiconductor layer includes Al, Ga and N. At least a part of the third semiconductor layer is provided between the third semiconductor portion and at least a part of the second electrode portion in the second direction. The third semiconductor layer includes a first portion including Al_{y1}Ga_{1-y1}N (0<y1≤1), and a second portion including Al_{y2}Ga_{1-y2}N (0≤y2<1, y2<y1). The second portion is between the first portion and the at least a part of the second electrode portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

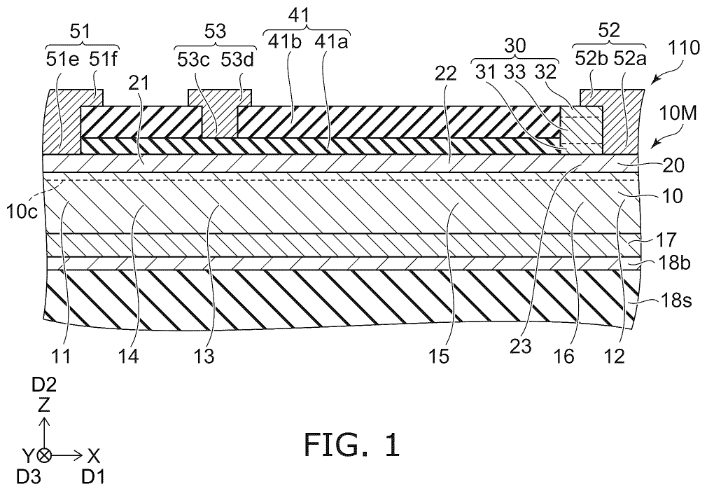

FIG. 1 is a schematic cross-sectional view illustrating a semiconductor device according to a first embodiment.

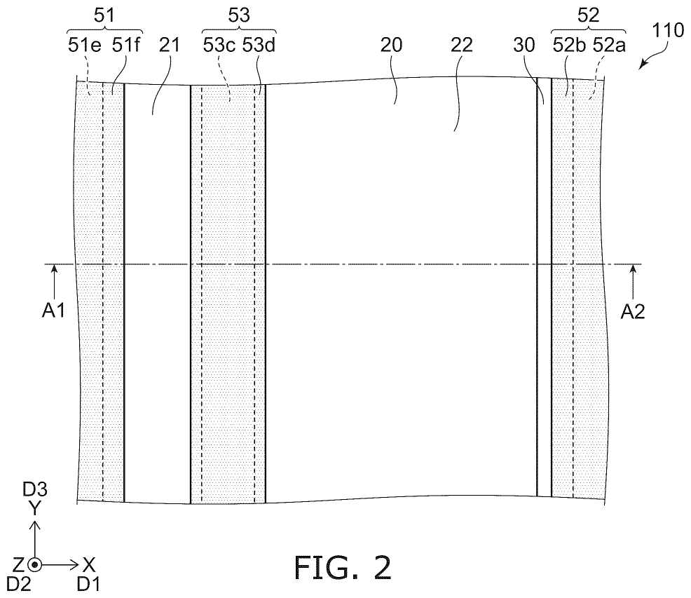

FIG. 2 is a schematic plan view illustrating the semiconductor device according to the first embodiment.

FIG. 1 is a sectional view taken along the line A1-A2 in FIG. 2.

As shown in FIGS. 1 and 2, a semiconductor device 110 according to the embodiment includes a first electrode 51, a second electrode 52, a third electrode 53, and a semiconductor member 10M.

A direction from the first electrode 51 to the second electrode 52 is along a first direction D1. The first direction D1 is defined as an X-axis direction. A direction perpendicular to the X-axis direction is defined as a Z-axis direction. A direction perpendicular to the X-axis direction and the Z-axis direction is a Y-axis direction.

As shown in FIG. 1, the second electrode 52 includes a first electrode portion 52a and a second electrode portion 52b. The second electrode portion 52b is connected to the first electrode portion 52a.

A position of the third electrode 53 in the first direction D1 is between a position of the first electrode 51 in the first direction D1 and a position of the second electrode 52 in the first direction D1.

The semiconductor member 10M includes a first semiconductor layer 10, a second semiconductor layer 20, and a third semiconductor layer 30.

The first semiconductor layer 10 includes Alₓ₁Ga₁₋ₓ₁N (0≤x1<1). The composition ratio x1 is, for example, not less than 0 and not more than 0.15. The first semiconductor layer 10 may be, for example, a GaN layer.

The first semiconductor layer 10 includes a first partial region 11, a second partial region 12, a third partial region 13, a fourth partial region 14, a fifth partial region 15, and a sixth partial region 16. A second direction D2 from the first partial region 11 to the first electrode 51 crosses the first direction D1. The second direction D2 may be, for example, the Z-axis direction.

A direction from the second partial region 12 to the first electrode portion 52a is along the second direction D2. A direction from the sixth partial region 16 to the second electrode portion 52b is along the second direction D2. A direction from the third partial region 13 to the third electrode 53 is along the second direction D2.

A position of the fourth partial region 14 in the first direction D1 is between a position of the first partial region 11 in the first direction D1 and a position of the third partial region 13 in the first direction D1. A position of the fifth partial region 15 in the first direction D1 is between the position of the third partial region 13 in the first direction D1 and a position of the second partial region 12 in the first direction D1. A position of the sixth partial region 16 in the first direction D1 is between the position of the fifth partial region 15 in the first direction D1 and the position of the second partial region 12 in the first direction D1.

The second semiconductor layer 20 includes Alₓ₂Ga₁₋ₓ₂N (0<x2<1, x1<x2). The composition ratio x2 may be, for example, not less than 0.15 and not more than 0.4. The second semiconductor layer 20 is, for example, an AlGaN layer. 30

The second semiconductor layer 20 includes a first semiconductor portion 21, a second semiconductor portion 22, and a third semiconductor portion 23. A direction from the fourth partial region 14 to the first semiconductor portion 21 is along the second direction D2. A direction from the fifth partial region 15 to the second semiconductor portion 22 is along the second direction D2. Ae direction from the sixth partial region 16 to the third semiconductor portion 23 is along the second direction D2.

The third semiconductor layer 30 includes, for example, Al, Ga, and N. The third semiconductor layer 30 may be, for example, an AlGaN layer. At least a part of the third semiconductor layer 30 is provided between the third semiconductor portion 23 and at least a part of the second electrode portion 52b in the second direction D2.

The third semiconductor layer 30 includes, for example, a first portion 31 and a second portion 32. The first portion 31 includes Al_{y1}Ga_{1-y1}N (0<y1≤1). The second portion 32 includes Al_{y2}Ga_{1-y2}N (0≤y2<1, y2<y1). The second portion 32 is between the first portion 31 and at least a part of the second electrode portion 52b. The composition ratio y1 may be, for example, not less than 0.15 and not more than 0.8. The composition ratio y2 may be, for example, not less than 0 and less than 0.15.

A current flowing between the first electrode 51 and the second electrode 52 can be controlled by a potential of the third electrode 53. The potential of the third electrode 53 may be, for example, a potential based on the potential of the first electrode 51. The first electrode 51 functions, for example, as a source electrode. The second electrode 52 functions, for example, as a drain electrode. The third electrode 53 functions as, for example, a gate electrode. The semiconductor device 110 is, for example, a transistor.

The first semiconductor layer 10 includes a portion facing the second semiconductor layer 20. A carrier region 10c is formed in this portion. The carrier region 10c is, for example, a two-dimensional electron gas. The semiconductor device 110 is, for example, a HEMT (High Electron Mobility Transistor).

For example, a distance between the first electrode 51 and the third electrode 53 along the first direction D1 is shorter than a distance between the third electrode 53 and the second electrode 52 along the first direction D1. Thereby, it becomes easy to obtain stable operation.

As described above, in the embodiment, the second electrode 52 is provided with the first electrode portion 52a and the second electrode portion 52b. For example, the first electrode portion 52a may be in contact with the second semiconductor layer 20. The position of the second electrode portion 52b in the first direction D1 is between the position of the third electrode 53 in the first direction D1 and the position of the first electrode portion 52a in the first direction D1. For example, the third semiconductor layer 30 is provided under at least a part of the second electrode portion 52b. The direction from the third semiconductor layer 30 to the first electrode portion 52a is along the first direction D1. The second electrode portion 52b is, for example, an eaves portion.

As described above, the third semiconductor layer 30 is provided between the third semiconductor portion 23 and the second electrode portion 52b. The third semiconductor layer 30 includes a first portion 31 having a high Al composition ratio and a second portion 32 having a low Al composition ratio. For example, the first portion 31 is a portion that is in contact with the third semiconductor portion 23. The second portion 32 is a portion in contact with the second electrode portion 52b.

In the embodiment, the electric field is relaxed by providing the third semiconductor layer 30 between the third semiconductor portion 23 and the second electrode portion 52b. Thereby, it becomes easy to obtain a high breakdown voltage. In a first reference example, an insulating layer is provided between the third semiconductor portion 23 and the second electrode portion 52b. In this case as well, the electric field is relaxed. However, in the first reference example, carrier traps are likely to be formed in the insulating layer. Carriers accumulated in the trap become fixed and the operation tends to become unstable. For example, on-resistance tends to increase during operation.

In the embodiment, a semiconductor layer (third semiconductor layer 30) is provided between the third semiconductor portion 23 and the second electrode portion 52b. For example, even when the semiconductor layer (third semiconductor layer 30) includes traps, carriers captured in the traps can move. This suppresses operational instability. For example, an increase in on-resistance during operation can be suppressed. In the embodiment, a semiconductor device whose characteristics can be stabilized can be provided.

In the second reference example, a p-type or n-type semiconductor layer is provided between the third semiconductor portion 23 and the second electrode portion 52b. The electric field is also relaxed in the second reference example. However, there is a case where the p-type or n-type impurities included in this semiconductor layer may diffuse into other regions, destabilizing the characteristics.

In contrast, in the embodiment, the third semiconductor layer 30 between the third semiconductor portion 23 and the second electrode portion 52b does not need to include p-type or n-type impurities. This makes it possible to suppress destabilization of characteristics caused by diffusion of impurities.

For example, in the embodiment, Mg concentration in the third semiconductor layer 30 is 1×10¹⁷ cm⁻³ or less. The concentration of Si in the third semiconductor layer 30 may be 1×10¹⁷ cm⁻³ or less. Mg functions as a p-type impurity. Si functions as an n-type impurity.

In the embodiment, the composition ratio of Al changes in the third semiconductor layer 30. This generates, for example, a charge. The generation of charge may be based on polarization, for example. The polarization is based on changes in composition ratio. The charge may be generated at a position where the composition ratio changes and may be fixed at that position. The charge is, for example, a hole.

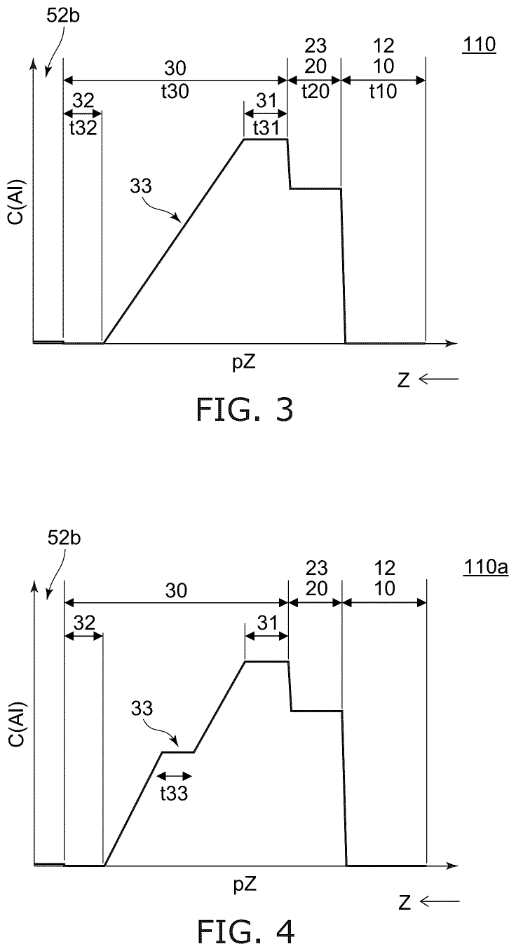

FIG. 3 is a schematic diagram illustrating the semiconductor device according to the first embodiment.

FIG. 3 illustrates the Al concentration profile in the semiconductor member 10M. The horizontal axis in FIG. 3 is the position pZ in the Z-axis direction. The vertical axis is the Al composition ratio C(Al).

As shown in FIG. 3, the composition ratio C(Al) in the first semiconductor layer 10 is low. The composition ratio C(Al) in the second semiconductor layer 20 is higher than the composition ratio C(Al) in the first semiconductor layer 10. In the third semiconductor layer 30, the composition ratio C(Al) in the first portion 31 is higher than the composition ratio C(Al) in the second portion 32.

In this example, the Al composition ratio C(Al) in the third semiconductor layer 30 decreases along the direction from the third semiconductor portion 23 to at least a part of the second electrode portion 52b. The third semiconductor layer 30 is a composition-graded layer.

In this example, the Al composition ratio y1 in the first portion 31 is greater than or equal to the Al composition ratio x2 in the second semiconductor layer 20. The composition ratio y1 may be higher than the composition ratio x2. For example, more charges can be obtained in the third semiconductor layer 30.

In the embodiment, the thickness t30 (see FIG. 3) of the third semiconductor layer 30 in the second direction D2 is, for example, not less than 100 nm and not more than 400 nm. The thickness t31 of the first portion 31 in the second direction D2 may be, for example, not less than 1 nm and not more than 10 nm. The thickness t32 of the second portion 32 in the second direction D2 may be, for example, not less than 1 nm and not more than 10 nm.

In the embodiment, the thickness t10 of the first semiconductor layer 10 in the second direction D2 may be, for example, not less than 100 nm and not more than 2000. The thickness t20 of the second semiconductor layer 20 in the second direction D2 may be, for example, not less than 10 nm and not more than 100 nm.

As shown in FIGS. 1 and 3, the third semiconductor layer 30 may further include a third portion 33. The third portion 33 is provided between the first portion 31 and the second portion 32. The third portion 33 includes Al_{y3}Ga_{1-y3}N (0<y3<1, y2<y3<y1).

As shown in FIG. 1, the semiconductor device 110 may further include a base 18s and a nitride layer 18b. The base 18s may be, for example, a silicon substrate. The nitride layer 18b includes Al, Ga, and N. The nitride layer 18b includes, for example, an AlGaN layer. The nitride layer 18b is provided between the base 18s and the semiconductor member 10M. The nitride layer 18b is, for example, a buffer layer.

As shown in FIG. 1, in this example, the semiconductor device 110 further includes an intermediate nitride layer 17. The intermediate nitride layer 17 is provided between nitride layer 18b and first semiconductor layer 10. The intermediate nitride layer 17 includes Ga and N. The intermediate nitride layer 17 includes carbon. The concentration of carbon in the intermediate nitride layer 17 is higher than the concentration of carbon in the first semiconductor layer 10. For example, the first semiconductor layer 10 does not include carbon. For example, high crystallinity can be easily obtained by the intermediate nitride layer 17. By the intermediate nitride layer 17, for example, a high breakdown voltage can be easily obtained.

In this example, the third electrode 53 includes a third electrode portion 53c and a fourth electrode portion 53d. The fourth electrode portion 53d is connected to the third electrode portion 53c. A position of the fourth electrode portion 53d in the first direction D1 is between a position of the third electrode portion 53c in the first direction D1 and a position of the second electrode portion 52b in the first direction D1. A position of at least a part of the third electrode portion 53c in the second direction D2 is between a position of the first semiconductor layer 10 in the second direction D2 and a position of the fourth electrode portion 53d in the second direction D2. The fourth electrode portion 53d is, for example, an eaves portion.

In this example, the first electrode 51 includes a fifth electrode portion 51e and a sixth electrode portion 51f. The sixth electrode portion 51f is connected to the fifth electrode portion 51e. A position of the sixth electrode portion 51f in the first direction D1 is between a position of the fifth electrode portion 51e in the first direction D1 and a position of the third electrode 53 in the first direction D1. A position of at least a part of the fifth electrode portion 51e in the second direction D2 is between a position of the first semiconductor layer 10 in the second direction D2 and the position of the sixth electrode portion 51f in the second direction D2. The sixth electrode portion 51f is, for example, an eaves portion.

As shown in FIG. 2, the first electrode 51, the second electrode 52, and the third electrode 53 may extend along a third direction D3. The third direction D3 crosses a plane including the first direction D1 and the second direction D2. The third direction D3 is, for example, the Y-axis direction.

For example, the first electrode portion 52a, the second electrode portion 52b, the third electrode portion 53c, the fourth electrode portion 53d, the fifth electrode portion 51e, and the sixth electrode portion 51f may extend along the third direction D3.

As shown in FIG. 1, the semiconductor device 110 may further include a first insulating member 41. In this example, the first insulating member 41 includes a first insulating film 41a and a second insulating film 41b. The first insulating film 41a is between the second semiconductor layer 20 and the second insulating film 41b. In one example, the first insulating film 41a includes silicon and nitrogen. For example, the second semiconductor layer 20 is protected by the first insulating film 41a. In one example, the second insulating film 41b includes silicon and oxygen. The second insulating film 41b suppresses, for example, impurities (such as water) from entering from the outside.

As shown in FIG. 1, in this example, at least a part of the first insulating member 41 (for example, the first insulating film 41a) is provided between the third partial region 13 and the third electrode 53. At least a part of the first insulating member 41 functions as, for example, a gate insulating film.

Hereinafter, some examples regarding the composition ratio of Al in the third semiconductor layer 30 will be described.

FIG. 4 is a schematic diagram illustrating a semiconductor device according to the first embodiment.

The horizontal axis in FIG. 4 is the position pZ in the Z-axis direction. The vertical axis is the Al composition ratio C (Al). As shown in FIG. 4, in a semiconductor device 110a according to the embodiment, the third semiconductor layer 30 includes the first portion 31, the second portion 32, and the third portion 33. The thickness t33 of the third portion 33 in the second direction D2 may be, for example, not less than 1 nm and not more than 10 nm. Except for the above, the configuration of the semiconductor device 110a may be the same as the configuration of the semiconductor device 110.

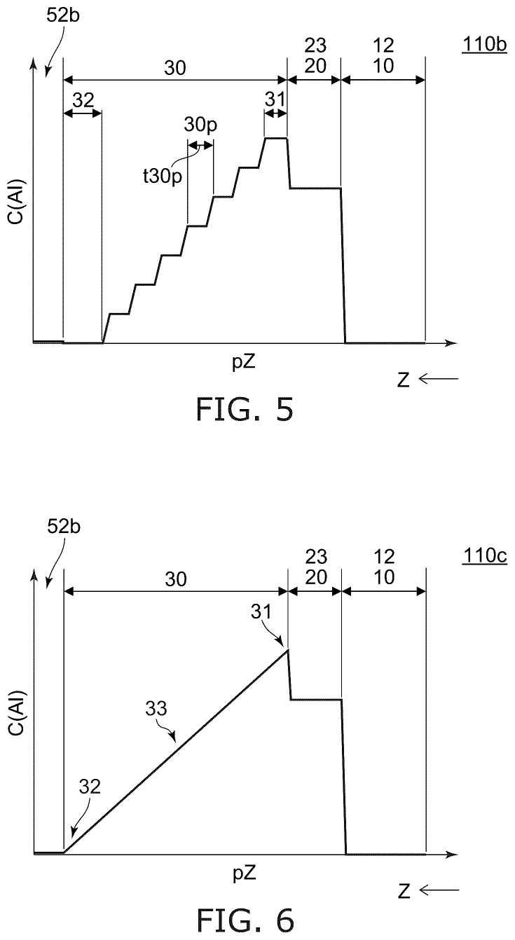

FIG. 5 is a schematic diagram illustrating a semiconductor device according to the first embodiment.

The horizontal axis in FIG. 5 is the position pZ in the Z-axis direction. The vertical axis is the Al composition ratio C (Al). As shown in FIG. 5, in a semiconductor device 110b according to the embodiment, the third semiconductor layer 30 includes a plurality of portions 30p. The first portion 31, the second portion 32, the third portion 33, etc. may be part of the plurality of portions 30p. Except for the above, the configuration of the semiconductor device 110b may be the same as the configuration of the semiconductor device 110.

The plurality of portions 30p are arranged along the second direction D2 (Z-axis direction). The Al composition ratio in each of the plurality of portions 30p is substantially constant. The thickness t30p of each of the plurality of portions 30p in the second direction is 10 nm or less. The thickness t30p may be 1 nm or more.

In the examples of the semiconductor device 110, the semiconductor device 110a, and the semiconductor device 110b, charges (for example, holes) are generated at positions in the Z-axis direction where the Al composition ratio C (Al) changes. By the distance between the plurality of positions where the composition ratio C (Al) changes being short, the concentration of generated charges (holes) is increased. Thereby, it becomes easy for carriers caught in the trap to move. Alternatively, the captured carrier is neutralized. Thereby, carrier accumulation during operation is more effectively suppressed and fluctuations in characteristics are more effectively suppressed.

For example, by setting the thickness t30p of each of the plurality of portions 30p in the second direction to 10 nm or less, the distance between the plurality of positions where the composition ratio C (Al) changes is effectively shortened. Fluctuations in characteristics can be more effectively suppressed.

FIG. 6 is a schematic diagram illustrating a semiconductor device according to the first embodiment.

The horizontal axis in FIG. 6 is the position pZ in the Z-axis direction. The vertical axis is the Al composition ratio C (Al). As shown in FIG. 6, in a semiconductor device 110c according to the embodiment, the Al composition ratio C (Al) in the third semiconductor layer 30 changes continuously. Except for the above, the configuration of the semiconductor device 110c may be the same as the configuration of the semiconductor device 110. In the semiconductor device 110c, the Al composition ratio C (Al) monotonically decreases along the direction from the third semiconductor portion 23 to at least a part of the second electrode portion 52b. The Al composition ratio C (Al) may change linearly or curved. In the semiconductor device 110c as well, a semiconductor device whose characteristics can be stabilized can be provided.

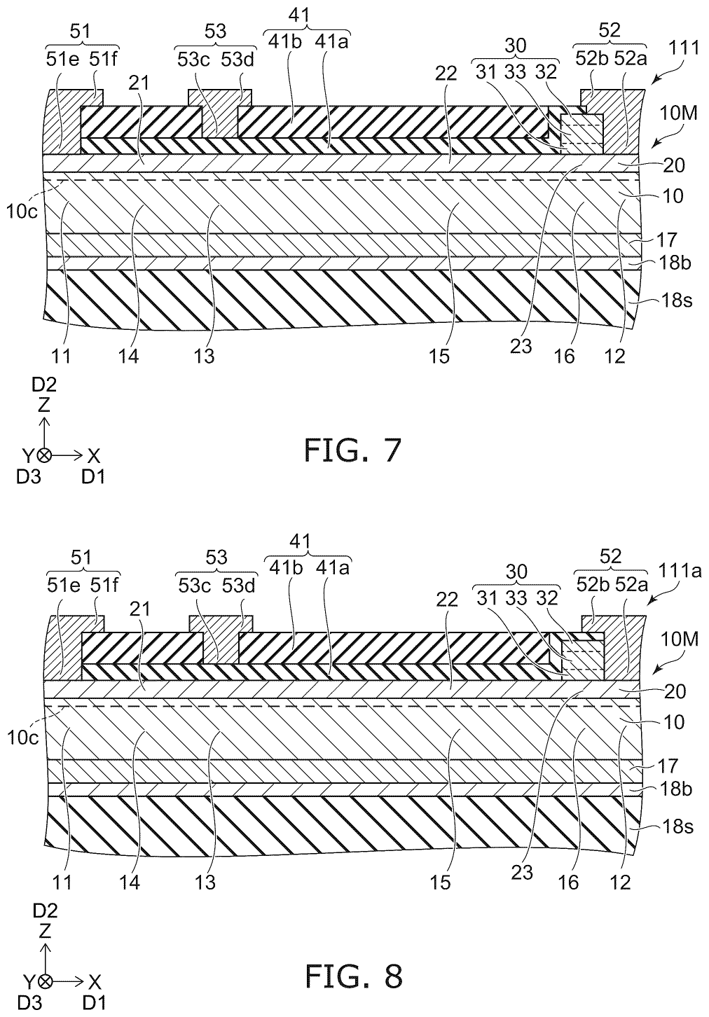

FIGS. 7 and 8 are schematic cross-sectional views illustrating a semiconductor device according to the first embodiment.

FIGS. 7 and 8 are cross-sectional views corresponding to the A1-A2 line cross section in FIG. 2.

As shown in FIG. 7, in a semiconductor device 111 according to the embodiment, at least a part of the first insulating member 41 is located between the third semiconductor layer 30 and the second electrode portion 52b in the second direction D2. The configuration of the semiconductor device 111 except for this may be the same as the configuration of the semiconductor device 110 (and the semiconductor devices 110a to 110c). In the semiconductor device 111, at least a part of the first insulating film 41a is provided between a part of the third semiconductor layer 30 and the second electrode portion 52b in the second direction D2.

As shown in FIG. 8, also in a semiconductor device 111a according to the embodiment, at least a part of the first insulating member 41 is located between the third semiconductor layer 30 and the second electrode portion 52b in the second direction D2. The configuration of the semiconductor device 111a except for this may be the same as the configuration of the semiconductor device 110 (and the semiconductor devices 110a to 110c). In the semiconductor device 111a, at least a part of the first insulating film 41a is provided between all of the third semiconductor layer 30 and the second electrode portion 52b in the second direction D2. By at least a part of the first insulating film 41a covering all of the third semiconductor layer 30 in the second direction D2, it becomes easier to maintain a high concentration of charges (for example, holes), for example.

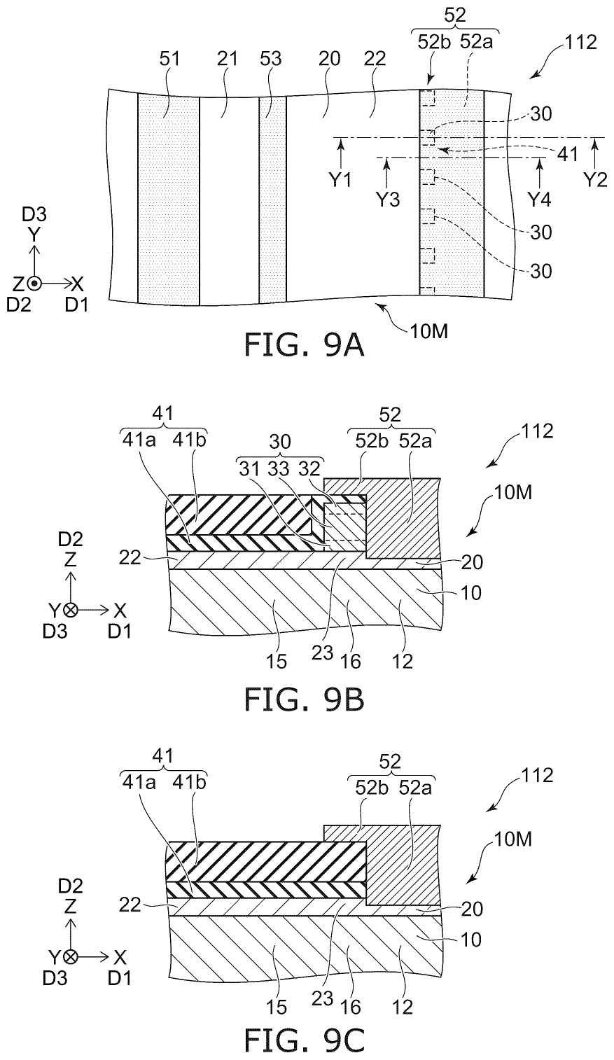

FIGS. 9A to 9C are schematic diagrams illustrating a semiconductor device according to the first embodiment.

FIG. 9A is a plan view. FIG. 9B is a sectional view taken along the line Y1-Y2 in FIG. 9A. FIG. 9C is a sectional view taken along the line Y3-Y4 in FIG. 9A.

As shown in FIG. 9A, in a semiconductor device 112 according to the embodiment, the semiconductor member 10M includes a plurality of the third semiconductor layers 30. The configuration of the semiconductor device 112 except for this may be the same as the configuration of the semiconductor device 110 (and the semiconductor devices 110a to 110c).

The plurality of third semiconductor layers 30 are arranged, for example, along the third direction D3 (for example, the Y-axis direction). The third direction D3 crosses a plane including the first direction D1 and the second direction D2. A direction from one of the plurality of third semiconductor layers 30 to another one of the plurality of third semiconductor layers 30 is along the third direction D3.

As shown in FIG. 9B, each of the plurality of third semiconductor layers 30 is provided between the third semiconductor portion 23 and the second electrode portion 52b in the second direction D2.

As shown in FIG. 9A, at least a part of the first insulating member 41 is between one of the multiple third semiconductor layers 30 and another one of the multiple third semiconductor layers 30 in the third direction. As shown in FIG. 9C, at least a part of the first insulating member 41 is provided between the third semiconductor portion 23 and the second electrode portion 52b.

In the semiconductor device 112, the island-shaped third semiconductor layers 30 and a part of the first insulating member 41 are arranged alternately in the third direction D3.

For example, by providing the third semiconductor layer 30 including the second portion 32 with a low Al composition ratio, it becomes difficult to form the carrier region 10c (two-dimensional electron gas). If the third semiconductor layer 30 has a stripe shape extending in the third direction D3, the on-resistance may increase excessively. For example, by providing a plurality of island-shaped third semiconductor layers 30, for example, the carrier region 10c can be appropriately formed, and an excessive increase in on-resistance can be suppressed.

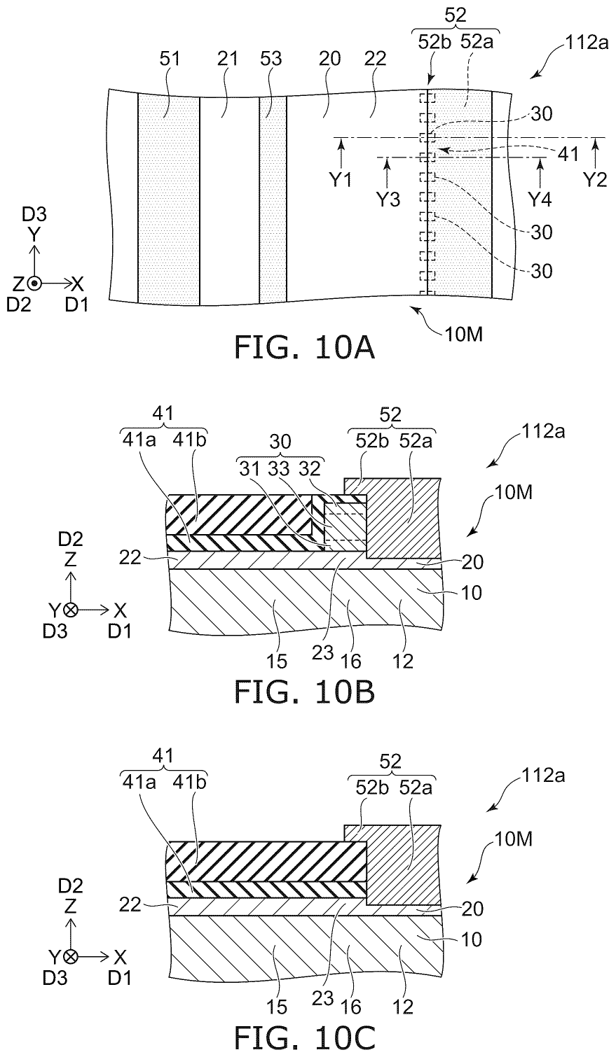

FIGS. 10A to 10C are schematic diagrams illustrating a semiconductor device according to the first embodiment.

FIG. 10A is a plan view. FIG. 10B is a sectional view taken along the line Y1-Y2 in FIG. 10A. FIG. 10C is a sectional view taken along the line Y3-Y4 in FIG. 10A.

As shown in FIG. 10A, also in a semiconductor device 112a according to the embodiment, the semiconductor member 10M includes a plurality of the third semiconductor layers 30. The configuration of the semiconductor device 112a except for this may be the same as the configuration of the semiconductor device 112.

As shown in FIG. 10A, in a semiconductor device 112a, the length of one of the plurality of third semiconductor layers 30 in the first direction D1 is longer than the length of one of the plurality of third semiconductor layers 30 in the third direction D3. Each of the plurality of third semiconductor layers 30 may have a stripe shape. A part of each of the multiple third semiconductor layers 30 may not overlap the second electrode portion 52b in the second direction D2.

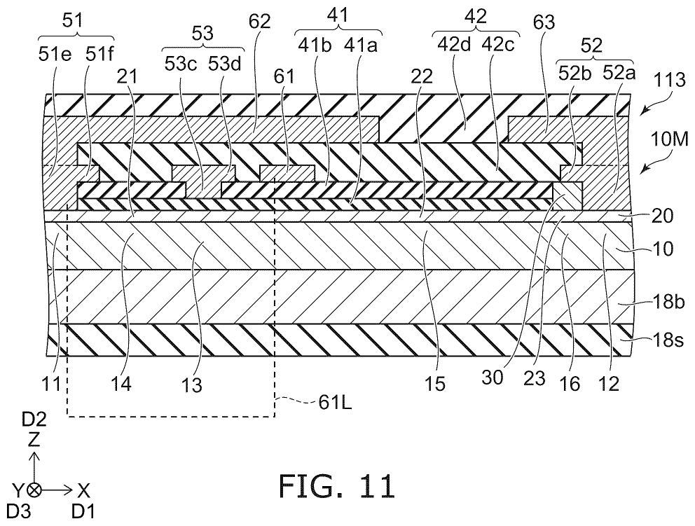

FIG. 11 is a schematic cross-sectional view illustrating a semiconductor device according to the first embodiment.

As shown in FIG. 11, a semiconductor device 113 according to the embodiment further includes a first conductive member 61. The configuration of the semiconductor device 113 except for this may be the same as the configuration of the semiconductor devices 110, 110a to 110c, 111, 111a, 112, and 112a.

The first conductive member 61 is electrically connected to the first electrode 51. In this example, the first conductive member 61 is electrically connected to the first electrode 51 by a connecting member 61L. A position of the first conductive member 61 in the first direction D1 is between the position of the third electrode 53 in the first direction D1 and the position of the second electrode 52 in the first direction D1. For example, the first conductive member 61 functions as a source field plate. By providing the first conductive member 61, the electric field is relaxed and a high breakdown voltage can be easily obtained.

The semiconductor device 113 may further include a second conductive member 62. The second conductive member 62 is electrically connected to the first electrode 51. For example, at least a part of the third electrode 53 is provided between the semiconductor member 10M and the second conductive member 62 in the second direction D2. The second conductive member 62 functions as a source field plate. By providing the second conductive member 62, the electric field is relaxed and a high breakdown voltage can be easily obtained.

The semiconductor device 113 may further include a third conductive member 63. The third conductive member 63 is electrically connected to the second electrode 52. The second electrode portion 52b is provided between the semiconductor member 10M and the third conductive member 63 in the second direction D2. The semiconductor device 113 may further include a second insulating member 42. At least a part of the second insulating member 42 is provided between the second electrode portion 52b and the third conductive member 63 in the second direction D2. The third conductive member 63 functions as, for example, a drain wiring. By providing the third conductive member 63, resistance is reduced and it becomes easy to obtain low on-resistance.

The second insulating member 42 includes, for example, a third insulating film 42c and a fourth insulating film 42d. The third insulating film 42c is between the first insulating member 41 and the fourth insulating film 42d. In one example, the third insulating film 42c and the fourth insulating film 42d include silicon and oxygen.

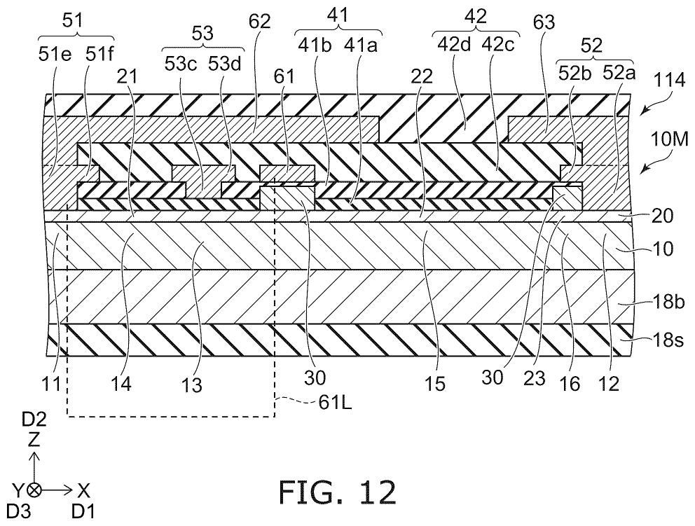

FIG. 12 is a schematic cross-sectional view illustrating a semiconductor device according to the first embodiment.

As shown in FIG. 12, a semiconductor device 114 according to the embodiment further includes the first conductive member 61. The configuration of the semiconductor device 114 except for this may be the same as the configuration of the semiconductor device 113.

A part of the third semiconductor layer 30 is provided between the second semiconductor portion 22 and the first conductive member 61. The Al composition ratio in the above-mentioned part of the third semiconductor layer 30 decreases along the direction from the second semiconductor layer 20 to the first conductive member 61. At least a part of the first insulating member 41 may be provided between the above-mentioned part of the third semiconductor layer 30 and the first conductive member 61.

For example, the first conductive member 61 functions as a source field plate. The third semiconductor layer 30 having a varying Al composition ratio is provided between the second semiconductor portion 22 and the first conductive member 61. As a result, the electric field can be relaxed and fluctuations in characteristics can be suppressed.

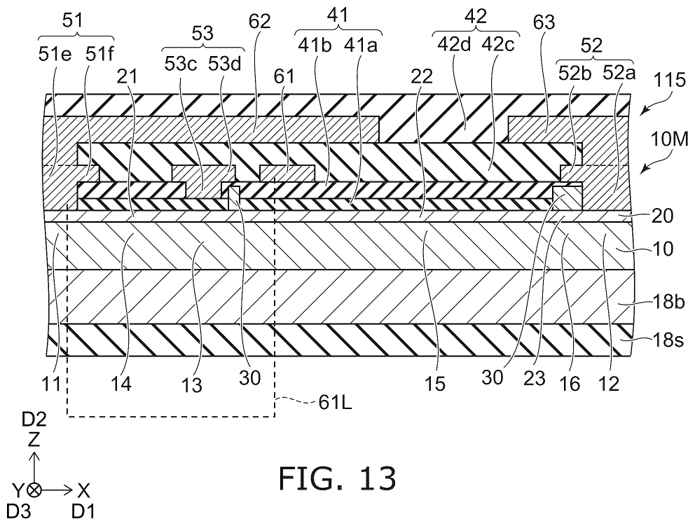

FIG. 13 is a schematic cross-sectional view illustrating a semiconductor device according to the first embodiment.

As shown in FIG. 13, in a semiconductor device 115 according to the embodiment, a part of the third semiconductor layer 30 is provided between the second semiconductor layer 20 and the fourth electrode portion 53d. The configuration of the semiconductor device 115 except for this may be the same as the configuration of the semiconductor device 113.

In the semiconductor device 115, the third electrode 53 includes the third electrode portion 53c and the fourth electrode portion 53d. The fourth electrode portion 53d is connected to the third electrode portion 53c. The position of the fourth electrode portion 53d in the first direction D1 is between the position of the third electrode portion 53c in the first direction D1 and the position of the second electrode portion 52b in the first direction D1. A part of the third semiconductor layer 30 is provided between the second semiconductor portion 22 and the fourth electrode portion 53d. The Al composition ratio in the above part of the third semiconductor layer 30 decreases along the direction from the second semiconductor portion 22 to the fourth electrode portion 53d. At least a part of the first insulating member 41 may be provided between the above-mentioned part of the third semiconductor layer 30 and the fourth electrode portion 53d.

In the semiconductor device 115, the electric field at the position overlapping the fourth electrode portion 53d is relaxed, and it becomes easy to obtain a high breakdown voltage. By providing a part of the third semiconductor layer 30 in which the Al composition ratio changes between the second semiconductor portion 22 and the fourth electrode portion 53d, for example, an increase in on-resistance during operation is suppressed.

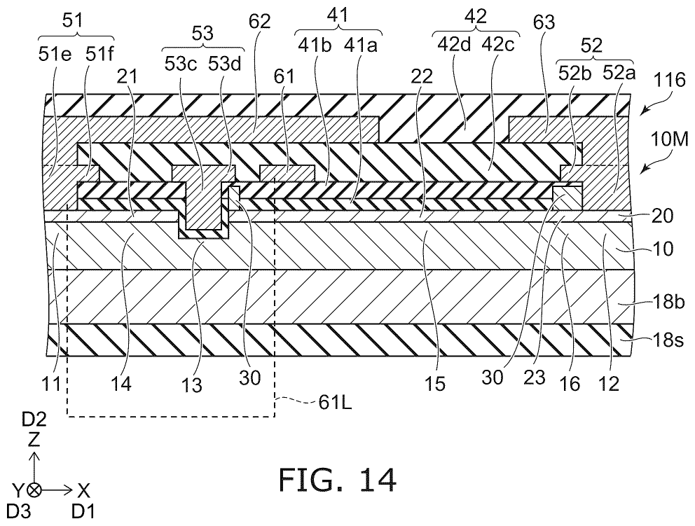

FIG. 14 is a schematic cross-sectional view illustrating a semiconductor device according to the first embodiment.

As shown in FIG. 14, in a semiconductor device 116 according to the embodiment, at least a part of the third electrode 53 is provided between the first semiconductor portion 21 and the second semiconductor portion 22 in the first direction. The configuration of the semiconductor device 116 except for this may be the same as the configuration of the semiconductor device 115.

In the semiconductor device 116, the third electrode 53 is, for example, a recessed gate electrode. It becomes easier to obtain a high threshold voltage. For example, normally-off operation is obtained.

At least a part of the third electrode 53 may be provided between the fourth partial region 14 and the fifth partial region 15 in the first direction. As shown in FIG. 14, at least a part of the first insulating member 41 may be provided between the first semiconductor layer 10 and the third electrode 53, and between the second semiconductor layer 20 and the third electrode 53.

In the semiconductor device 116, the third semiconductor layer 30 provided between the second semiconductor portion 22 and the fourth electrode portion 53d may be omitted.

### Second Embodiment

The second embodiment relates to a method for manufacturing a semiconductor device.

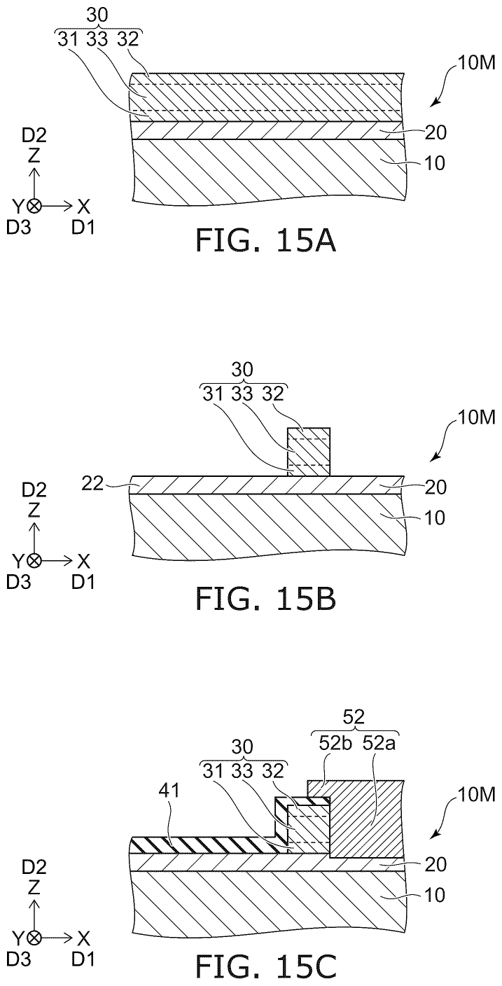

FIGS. 15A to 15C are schematic cross-sectional views illustrating a method for manufacturing the semiconductor device according to the second embodiment.

As shown in FIG. 15A, the third semiconductor layer 30 is formed on the second semiconductor layer 20 provided on the first semiconductor layer 10. The first semiconductor layer 10 includes Alₓ₁Ga₁₋ₓ₁N (0≤x1<1). The second semiconductor layer 20 includes Alₓ₂Ga₁₋ₓ₂N (0<x2<1, x1<x2). The third semiconductor layer 30 includes Al, Ga, and N. The third semiconductor layer 30 includes the first portion 31 including Al_{y1}Ga_{1-y1}N (0<y1≤1) and the second portion 32 including Al_{y2}Ga_{1-y2}N (0≤y2<1, y2<y1). The first portion 31 is between the second semiconductor layer 20 and the second portion 32.

The second direction D2 from the first semiconductor layer 10 to the second semiconductor layer 20 is along the Z-axis direction. The composition ratio of Al in the third semiconductor layer 30 may decrease in the direction away from the second semiconductor layer 20 in the Z-axis direction. The third semiconductor layer 30 may be, for example, a composition-graded layer in which the composition ratio of Al changes.

As shown in FIG. 15B, a part of the third semiconductor layer 30 is removed to expose a part of the second semiconductor layer 20.

As shown in FIG. 15C, an electrode (for example, the second electrode 52) is formed on at least a part of the exposed part of the second semiconductor layer 20 and on the third semiconductor layer 30 being remained. The electrode formed on at least a part of the exposed portion of the second semiconductor layer 20 corresponds to the first electrode portion 52a. The electrode formed on the third semiconductor layer 30 being remained corresponds to the second electrode portion 52b. A method for manufacturing a semiconductor device capable of stabilizing characteristics can be provided.

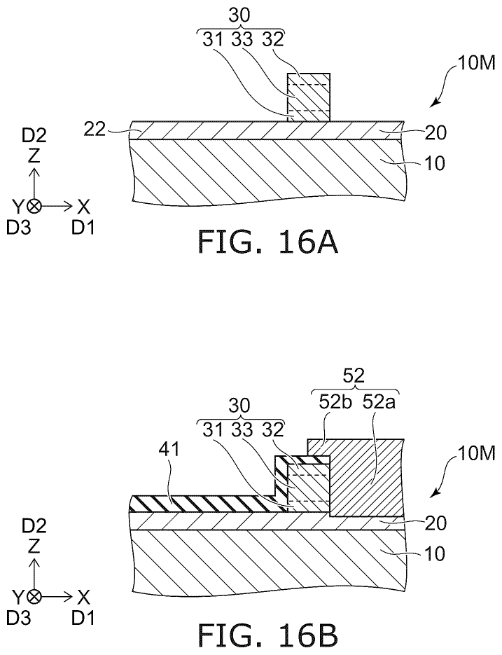

FIGS. 16A and 16B are schematic cross-sectional views illustrating a method for manufacturing the semiconductor device according to the second embodiment.

As shown in FIG. 16A, the third semiconductor layer 30 is formed on a part of the second semiconductor layer 20 provided on the first semiconductor layer 10. The first semiconductor layer 10 includes Alₓ₁Ga₁₋ₓ₁N (0≤x1<1). The second semiconductor layer 20 includes Alₓ₂Ga₁₋ₓ₂N (0<x2<1, x1<x2). The third semiconductor layer 30 includes Al, Ga, and N. The third semiconductor layer 30 includes the first portion 31 including Al_{y1}Ga_{1-y1}N (0<y1≤1) and the second portion 32 including Al_{y2}Ga_{1-y2}N (0≤y2<1, y2<y1). The first portion 31 is between the second semiconductor layer 20 and the second portion 32.

For example, a mask including an opening is formed on the second semiconductor layer 20. The third semiconductor layer 30 is formed on the second semiconductor layer 20 in the opening. The third semiconductor layer 30 is formed on a part of the second semiconductor layer 20.

The second direction D2 from the first semiconductor layer 10 to the second semiconductor layer 20 is along the Z-axis direction. The composition ratio of Al in the third semiconductor layer 30 may decrease in the direction away from the second semiconductor layer 20 in the Z-axis direction. The third semiconductor layer 30 may be, for example, a composition-graded layer in which the composition ratio of Al changes.

As shown in FIG. 16B, an electrode (for example, the second electrode 52) is formed on the other part of the second semiconductor layer 20 and on the third semiconductor layer 30. The electrode formed on the other part of the second semiconductor layer 20 corresponds to the first electrode portion 52a. The electrode formed on the third semiconductor layer 30 corresponds to the second electrode portion 52b. A method for manufacturing a semiconductor device capable of stabilizing characteristics can be provided.

Information regarding length and thickness can be obtained by electron microscopy, etc. Information regarding the composition of the material can be obtained by SIMS (Secondary Ion Mass Spectrometry), EDX (Energy dispersive X-ray spectroscopy), or the like.

The embodiments may include the following Technical proposals:

### Technical Proposal 1

A semiconductor device, comprising:
a first electrode;
a second electrode, a direction from the first electrode to the second electrode being along a first direction, the second electrode including a first electrode portion and a second electrode portion, the second electrode portion being connected to the first electrode portion;
a third electrode, a position of the third electrode in the first direction being between a position of the first electrode in the first direction and a position of the second electrode in the first direction; and
a semiconductor member,
the semiconductor member including
   a first semiconductor layer including Alₓ₁Ga₁₋ₓ₁N (0≤x1<1), the first semiconductor layer including a first partial region, a second partial region, a third partial region, a fourth partial region, a fifth partial region, and a sixth partial region, a second direction from the first partial region to the first electrode crossing the first direction, a direction from the second partial region to the first electrode portion being along the second direction, a direction from the sixth partial region to the second electrode portion being along the second direction, a direction from the third partial region to the third electrode being along the second direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction, a position of the sixth partial region in the first direction being between the position of the fifth partial region in the first direction and the position of the second partial region in the first direction,
   a second semiconductor layer including Alₓ₂Ga₁₋ₓ₂N (0<x2<1, x1<x2), the second semiconductor layer including a first semiconductor portion, a second semiconductor portion, and a third semiconductor portion, a direction from the fourth partial region to the first semiconductor portion being along the second direction, a direction from the fifth partial region to the second semiconductor portion being along the second direction, a direction from the sixth partial region to the third semiconductor portion being along the second direction, and
   a third semiconductor layer including Al, Ga and N, at least a part of the third semiconductor layer being provided between the third semiconductor portion and at least a part of the second electrode portion in the second direction, the third semiconductor layer including a first portion including Al_{y1}Ga_{1-y1}N (0<y1≤1), and a second portion including Al_{y2}Ga_{1-y2}N (0≤y2<1, y2<y1)the second portion being between the first portion and the at least a part of the second electrode portion.

### Technical Proposal 2

The semiconductor device according to Technical proposal 1, wherein
the y1 is higher than or equal to the x2.

### Technical Proposal 3

The semiconductor device according to Technical proposal 1, wherein
the y1 is higher than the x2.

### Technical Proposal 4

The semiconductor device according to any one of Technical proposals 1-3, wherein
the third semiconductor layer further includes a third portion provided between the first portion and the second portion, and
the third portion includes Al_{y3}Ga_{1-y3}N (0<y3<1, y2<y3<y1).

### Technical Proposal 5

The semiconductor device according to any one of Technical proposals 1-4, wherein
a composition ratio of Al in the third semiconductor layer decreases along a direction from the third semiconductor portion to the at least part of the second electrode portion.

### Technical Proposal 6

The semiconductor device according to Technical proposal 5, wherein
the third semiconductor layer includes a plurality of portions arranged along the second direction,
a composition ratio of Al in each of the plurality of portion is substantially constant, and
a thickness of each of the plurality of portions in the second direction is 10 nm or less.

### Technical Proposal 7

The semiconductor device according to any one of Technical proposals 1-6, wherein
a Mg concentration in the third semiconductor layer is 1×10¹⁷ cm⁻³ or less.

### Technical Proposal 8

The semiconductor device according to any one of Technical proposals 1-7, wherein
a thickness of the third semiconductor layer in the second direction is not less than 100 nm and not more than 400 nm.

### Technical Proposal 9

The semiconductor device according to any one of Technical proposals 1-8, further comprising:
a first insulating member,
at least a part of the first insulating member being provided between the third semiconductor layer and the second electrode portion in the second direction.

### Technical Proposal 10

The semiconductor device according to any one of Technical proposals 1-8, further comprising:
a first insulating member,
the semiconductor member including a plurality of the third semiconductor layers,
a direction from one of the plurality of third semiconductor layers to another one of the plurality of third semiconductor layers being along a third direction crossing a plane including the first direction and the second direction,
at least a part of the first insulating member being provided between the one of the plurality of third semiconductor layers and the other one of the plurality of third semiconductor layers in the third direction, and
the at least the part of the first insulating member being provided between the third semiconductor portion and the second electrode portion.

### Technical Proposal 11

The semiconductor device according to any one of Technical proposals 1-8, further comprising:
a first conductive member electrically connected to the first electrode,
a position of the first conductive member in the first direction being between the position of the third electrode in the first direction and the position of the second electrode in the first direction,
a part of the third semiconductor layer being provided between the second semiconductor portion and the first conductive member, and
a composition ratio of Al in the part of the third semiconductor layer decreasing along the direction from the second semiconductor layer to the first conductive member.

### Technical Proposal 12

The semiconductor device according to any one of Technical proposals 1-8, wherein
the third electrode includes a third electrode portion and a fourth electrode portion,
the fourth electrode portion is connected to the third electrode portion,
a position of the fourth electrode portion in the first direction is between a position of the third electrode portion in the first direction and a position of the second electrode portion in the first direction,
a part of the third semiconductor layer is provided between the second semiconductor portion and the fourth electrode portion, and
a composition ratio of Al in the part of the third semiconductor layer decreases along a direction from the second semiconductor portion to the fourth electrode portion.

### Technical Proposal 13

The semiconductor device according to Technical proposal 12, further comprising:
a first insulating member,
at least a part of the third electrode being provided between the first semiconductor portion and the second semiconductor portion in the first direction, and
at least a part of the first insulating member being provided between the first semiconductor layer and the third electrode, and between the second semiconductor layer and the third electrode.

### Technical Proposal 14

The semiconductor device according to any one of Technical proposals 1-8, further comprising:
a first insulating member,
at least a part of the third electrode being provided between the first semiconductor portion and the second semiconductor portion in the first direction, and
at least a part of the first insulating member being provided between the first semiconductor layer and the third electrode and between the second semiconductor layer and the third electrode.

### Technical Proposal 15

The semiconductor device according to any one of Technical proposals 1-14, further comprising:
a second conductive member electrically connected to the first electrode,
at least a part of the third electrode being provided between the semiconductor member and the second conductive member in the second direction.

### Technical Proposal 16

The semiconductor device according to any one of Technical proposals 1-15, further comprising:
a third conductive member electrically connected to the second electrode; and
a second insulating member,
the second electrode portion being provided between the semiconductor member and the third conductive member in the second direction, and
at least a part of the second insulating member being provided between the second electrode portion and the third conductive member in the second direction.

### Technical Proposal 17

The semiconductor device according to any one of Technical proposals 1-9, wherein
the second electrode portion extends along a third direction crossing a plane including the first direction and the second direction.

### Technical Proposal 18

The semiconductor device according to any one of Technical proposals 1-17, wherein
the x1 is not less than 0 and less than 0.15,
the x2 is not less than 0.15 and not more than 0.4,
the y1 is not less than 0.15 and not more than 0.8, and
the y2 is not less than 0 and less than 0.15.

### Technical Proposal 19

A method for manufacturing a semiconductor device, comprising:
forming a third semiconductor layer including Al, Ga and N on a second semiconductor layer including Alₓ₂Ga₁₋ₓ₂N (0<x2<1, x1<x2) provided on a first semiconductor layer including Alₓ₁Ga₁₋ₓ₁N (0≤x1<1), the third semiconductor layer including a first portion including Al_{y1}Ga_{1-y1}N (0<y1≤1), and a second portion including Al_{y2}Ga_{1-y2}N (0≤y2<1, y2<y1), the second portion being between the first portion and the at least a part of the second electrode portion;
removing a part of the third semiconductor layer to expose a part of the second semiconductor layer; and
forming an electrode on at least a part of the exposed part of the second semiconductor layer and on the remaining third semiconductor layer.

### Technical Proposal 20

A method for manufacturing a semiconductor device, comprising:
forming a third semiconductor layer including Al, Ga and N on a second semiconductor layer including Alₓ₂Ga₁₋ₓ₂N (0<x2<1, x1<x2) provided on a first semiconductor layer including Alₓ₁Ga₁₋ₓ₁N (0≤x1<1), the third semiconductor layer including a first portion including Al_{y1}Ga_{1-y1}N (0<y1≤1), and a second portion including Al_{y2}Ga_{1-y2}N (0≤y2<1, y2<y1), the second portion being between the first portion and the at least a part of the second electrode portion; and
forming an electrode on another part of the second semiconductor layer and on the third semiconductor layer.

According to the embodiment, a semiconductor device whose characteristics can be stabilized and a method for manufacturing the same are provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor device such as electrodes, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices and all methods for manufacturing the same practicable by an appropriate design modification by one skilled in the art based on the semiconductor devices and the methods for manufacturing the same described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode, a direction from the first electrode to the second electrode being along a first direction, the second electrode including a first electrode portion and a second electrode portion, the second electrode portion being connected to the first electrode portion;
a third electrode, a position of the third electrode in the first direction being between a position of the first electrode in the first direction and a position of the second electrode in the first direction; and
a semiconductor member,
the semiconductor member including
a first semiconductor layer including Alₓ₁Ga₁₋ₓ₁N (0≤x1<1), the first semiconductor layer including a first partial region, a second partial region, a third partial region, a fourth partial region, a fifth partial region, and a sixth partial region, a second direction from the first partial region to the first electrode crossing the first direction, a direction from the second partial region to the first electrode portion being along the second direction, a direction from the sixth partial region to the second electrode portion being along the second direction, a direction from the third partial region to the third electrode being along the second direction, a position of the fourth partial region in the first direction being between a position of the first partial region in the first direction and a position of the third partial region in the first direction, a position of the fifth partial region in the first direction being between the position of the third partial region in the first direction and a position of the second partial region in the first direction, a position of the sixth partial region in the first direction being between the position of the fifth partial region in the first direction and the position of the second partial region in the first direction,
a second semiconductor layer including Alₓ₂Ga₁₋ₓ₂N (0<x2<1, x1<x2), the second semiconductor layer including a first semiconductor portion, a second semiconductor portion, and a third semiconductor portion, a direction from the fourth partial region to the first semiconductor portion being along the second direction, a direction from the fifth partial region to the second semiconductor portion being along the second direction, a direction from the sixth partial region to the third semiconductor portion being along the second direction, and
a third semiconductor layer including Al, Ga and N, at least a part of the third semiconductor layer being provided between the third semiconductor portion and at least a part of the second electrode portion in the second direction, the third semiconductor layer including a first portion including Al_{y1}Ga_{1-y1}N (0<y1≤1), and a second portion including Al_{y2}Ga_{1-y2}N (0≤y2<1, y2<y1), the second portion being between the first portion and the at least a part of the second electrode portion.

2. The device according to claim 1, wherein
the y1 is higher than or equal to the x2.

3. The device according to claim 1, wherein
the y1 is higher than the x2.

4. The device according to claim 1, wherein
the third semiconductor layer further includes a third portion provided between the first portion and the second portion, and
the third portion includes Al_{y3}Ga_{1-y3}N (0<y3<1, y2<y3<y1).

5. The device according to claim 1, wherein
a composition ratio of Al in the third semiconductor layer decreases along a direction from the third semiconductor portion to the at least part of the second electrode portion.

6. The device according to claim 5, wherein
the third semiconductor layer includes a plurality of portions arranged along the second direction,
a composition ratio of Al in each of the plurality of portion is substantially constant, and
a thickness of each of the plurality of portions in the second direction is 10 nm or less.

7. The device according to claim 1, wherein
a Mg concentration in the third semiconductor layer is 1×10¹⁷ cm⁻³ or less.

8. The device according to claim 1, wherein
a thickness of the third semiconductor layer in the second direction is not less than 100 nm and not more than 400 nm.

9. The device according to claim 1, further comprising:
a first insulating member,
at least a part of the first insulating member being provided between the third semiconductor layer and the second electrode portion in the second direction.

10. The device according to claim 1, further comprising:
a first insulating member,
the semiconductor member including a plurality of the third semiconductor layers,
a direction from one of the plurality of third semiconductor layers to another one of the plurality of third semiconductor layers being along a third direction crossing a plane including the first direction and the second direction,
at least a part of the first insulating member being provided between the one of the plurality of third semiconductor layers and the other one of the plurality of third semiconductor layers in the third direction, and
the at least the part of the first insulating member being provided between the third semiconductor portion and the second electrode portion.

11. The device according to claim 1, further comprising:
a first conductive member electrically connected to the first electrode,
a position of the first conductive member in the first direction being between the position of the third electrode in the first direction and the position of the second electrode in the first direction,
a part of the third semiconductor layer being provided between the second semiconductor portion and the first conductive member, and
a composition ratio of Al in the part of the third semiconductor layer decreasing along the direction from the second semiconductor layer to the first conductive member.

12. The device according to claim 1, wherein
the third electrode includes a third electrode portion and a fourth electrode portion,
the fourth electrode portion is connected to the third electrode portion,
a position of the fourth electrode portion in the first direction is between a position of the third electrode portion in the first direction and a position of the second electrode portion in the first direction,
a part of the third semiconductor layer is provided between the second semiconductor portion and the fourth electrode portion, and
a composition ratio of Al in the part of the third semiconductor layer decreases along a direction from the second semiconductor portion to the fourth electrode portion.

13. The device according to claim 12, further comprising:
a first insulating member,
at least a part of the third electrode being provided between the first semiconductor portion and the second semiconductor portion in the first direction, and
at least a part of the first insulating member being provided between the first semiconductor layer and the third electrode, and between the second semiconductor layer and the third electrode.

14. The device according to claim 1, further comprising:
a first insulating member,
at least a part of the third electrode being provided between the first semiconductor portion and the second semiconductor portion in the first direction, and
at least a part of the first insulating member being provided between the first semiconductor layer and the third electrode and between the second semiconductor layer and the third electrode.

15. The device according to claim 1, further comprising:
a second conductive member electrically connected to the first electrode,
at least a part of the third electrode being provided between the semiconductor member and the second conductive member in the second direction.

16. The device according to claim 1, further comprising:
a third conductive member electrically connected to the second electrode; and
a second insulating member,
the second electrode portion being provided between the semiconductor member and the third conductive member in the second direction, and
at least a part of the second insulating member being provided between the second electrode portion and the third conductive member in the second direction.

17. The device according to claim 1, wherein
the second electrode portion extends along a third direction crossing a plane including the first direction and the second direction.

18. The device according to claim 1, wherein
the x1 is not less than 0 and less than 0.15,
the x2 is not less than 0.15 and not more than 0.4,
the y1 is not less than 0.15 and not more than 0.8, and
the y2 is not less than 0 and less than 0.15.

19. A method for manufacturing a semiconductor device, comprising:
forming a third semiconductor layer including Al, Ga and N on a second semiconductor layer including Alₓ₂Ga₁₋ₓ₂N (0<x2<1, x1<x2) provided on a first semiconductor layer including Alₓ₁Ga₁₋ₓ₁N (0≤x1<1), the third semiconductor layer including a first portion including Al_{y1}Ga_{1-y1}N (0<y1≤1), and a second portion including Al_{y2}Ga_{1-y2}N (0≤y2<1, y2<y1), the second portion being between the first portion and the at least a part of the second electrode portion;
removing a part of the third semiconductor layer to expose a part of the second semiconductor layer; and
forming an electrode on at least a part of the exposed part of the second semiconductor layer and on the remaining third semiconductor layer.

20. A method for manufacturing a semiconductor device, comprising:
forming a third semiconductor layer including Al, Ga and N on a second semiconductor layer including Alₓ₂Ga₁₋ₓ₂N (0<x2<1, x1<x2) provided on a first semiconductor layer including Alₓ₁Ga₁₋ₓ₁N (0≤x1<1), the third semiconductor layer including a first portion including Al_{y1}Ga_{1-y1}N (0<y1≤1), and a second portion including Al_{y2}Ga_{1-y2}N (0≤y2<1, y2<y1), the second portion being between the first portion and the at least a part of the second electrode portion; and
forming an electrode on another part of the second semiconductor layer and on the third semiconductor layer.
